(19) United States
(12) Patent Application Publication
(10) Pub. No.: US 2023/0130341 A1
(43) Pub. Date: Apr. 27, 2023

(54) BOTTOM-EMITTING MULTIJUNCTION VCSEL ARRAY

(71) Applicant: SHENZHEN RAYSEES AI TECHNOLOGY Co. Ltd., Shenzhen, Guangdong (CN)

(72) Inventors: Dongseok Kang, Sunnyvale, CA (US); Siva Kumar Lanka, Reno, NV (US); Yongxiang He, Sunnyvale, CA (US); Yang Wang, Hefei (CN)

(73) Assignee: SHENZHEN RAYSEES AI TECHNOLOGY Co. Ltd., Shenzhen, Guangdong (CN)

(21) Appl. No.: 17/921,015

(22) PCT Filed: May 22, 2020
(86) PCT No.: PCT/CN2020/091709

§ 371 Date: Oct. 24, 2022

Related U.S. Application Data
(60) Provisional application No. 63/004,359, filed on Apr. 2, 2020.

(51) Int. Cl. H01S 5/024; H01S 5/42; H01S 5/183; H01S 5/0236; H01S 5/042; H01S 5/0234

(52) U.S. Cl. CPC H01S 5/02461; H01S 5/0234; H01S 5/0236; H01S 5/423; H01S 5/04256; H01S 5/18305; H01S 5/18361; H01S 5/18388; H01S 5/18397; H01S 5/3416; H01S 5/18311

(57) ABSTRACT

A bottom-emitting multijunction VCSEL array includes a first reflector region, a multijunction active region, and a second reflector region. In one aspect, the multijunction VCSEL array is attached to a submount by flip-chip bonding. In another aspect, the multijunction VCSEL array further includes a contact layer formed between the first reflector region and the substrate. The multijunction VCSEL array is attached to a submount by flip-chip bonding.

### CROSS-REFERENCE TO RELATED APPLICATION

This application claims priority to U.S. Provisional Pat. Application Ser. No. 63/004,359, filed Apr. 2, 2020, the entire content of which is incorporated herein by reference.

### FIELD OF INVENTION

This invention generally relates to Vertical Cavity Surface Emitting Laser (VCSEL) arrays and specifically to bottom-emitting multijunction VCSEL arrays.

### BACKGROUND OF THE INVENTION

Compared to edge-emitting semiconductor lasers with a horizontal Fabry-Perot resonator and cleaved facets acting as mirrors, VCSELs have a vertical cavity and emit a circular beam normal to the surface. VCSELs have many advantages over edge-emitting semiconductor lasers such as compact size, small beam spot, low beam divergence, narrow spectral width, low sensitivity to temperature, fast rise time, and ease of fabricating two-dimensional (2-D) VCSEL array, etc.

In recent years, VCSEL arrays become a prominent player in three-dimensional (3D) sensing applications. For instance, many smartphones are equipped with a VCSEL-array-based 3D sensor using the Time-of-Flight (ToF) method or the structured light method for facial recognition. In addition, VCSEL-array-based systems, such as light detection and ranging (LIDAR) systems, have entered the emerging autonomous vehicle landscape. LIDAR systems may help recognize running vehicles and walking or standing pedestrians on a road effectively and quickly, and thus may prevent fatal accidents and mitigate one of the most challenging issues a driverless car faces.

LIDAR is based on ToF measurement principles. It illuminates a scene with a laser beam. The beam is scattered by objects of the scene. It then detects the bounce-back of the beam. The distance is calculated by the time it takes for the beam to travel to the objects and back from them. In VCSEL-based LIDAR applications, the detection range is often determined by the output power and thus high-power VCSELs are desirable for LIDAR applications.

Multijunction VCSEL represents one approach to increase the output power of VCSEL. In a multijunction VCSEL structure, the gain volume is increased. For example, two or more than two multi-quantum-well (MQW) active regions may be configured in series to form a multijunction active region. As the coherent light is generated in each MQW active region, the output power may be multiplied. In addition, the slope efficiency is improved. However, while the output power is increased, so is the heat generated in the multijunction active region, which may make overheating issues more severe in a multijunction VCSEL than those in a VCSEL with a single MQW active region. Overheating may cause problems such as reduced power output, higher thresholds, and wavelength change of the VCSEL output.

Thus, efficient heat dissipation is important for a multijunction VCSEL, and especially for a multijunction VCSEL array. When a top-emitting multijunction VCSEL is mounted, the top p+ contact layer faces upward and the substrate is bonded to a submount, i.e., the heat sink. As the heat is generated in the multijunction active region, the heat has to go through the substrate to reach the heat sink. The substrate, however, has to be thick enough, e.g., 100-600 micrometers, to provide a stable support for a VCSEL array. As such, heat dissipation of a top-emitting multijunction VCSEL is inherently affected by the substrate.

Therefore, there exists a need to improve heat dissipation of a multijunction VCSEL array.

### SUMMARY OF THE INVENTION

The present invention discloses methods and apparatus for bottom-emitting multijunction VCSEL array devices. In one aspect, a bottom-emitting multijunction VCSEL array device includes a submount and a VCSEL array chip attached to the submount. The VCSEL array chip includes a substrate and VCSEL structures formed in a first chip region above the substrate. Each VCSEL structure includes a first reflector region formed above the substrate, a multijunction active region including MQW active regions formed above the first reflector region, a second reflector region formed above the multijunction active region, and a pad metal layer formed above the second reflector region. The pad metal layer faces the submount and is between the substrate and the submount after the VCSEL array chip is attached to the submount.

In another aspect, a method for fabricating a bottom-emitting multijunction VCSEL array device includes forming VCSEL structures in a first chip region above a substrate of a VCSEL array chip and attaching the VCSEL array chip on a submount. Forming the VCSEL structures includes growing a first reflector region above the substrate, growing a multijunction active region above the first reflector region, growing a second reflector region above the multijunction active region, and forming a pad metal layer above the second reflector region. The pad metal layer faces the submount and is between the substrate and the submount after the VCSEL array chip is attached on the submount.

In another aspect, a bottom-emitting multijunction VCSEL array device includes a submount and a VCSEL array chip attached to the submount. The VCSEL array chip includes a substrate and VCSEL structures formed in a first chip region above the substrate. Each VCSEL structure includes a contact layer formed above the substrate, a first reflector region formed above the contact layer, a multijunction active region formed above the first reflector region, a second reflector region formed above the multijunction active region, and a pad metal layer formed above the second reflector layer and electrically connected to the contact layer. The pad metal layer faces the submount and is between the substrate and the submount after the VCSEL array chip is attached to the submount.

### BRIEF DESCRIPTION OF THE DRAWINGS

The subject matter, which is regarded as the invention, is particularly pointed out and distinctly claimed in the claims at the conclusion of the specification. The foregoing and other features and also the advantages of the invention will be apparent from the following detailed description taken in conjunction with the accompanying drawings. Additionally, the leftmost digit of a reference number identifies the drawing in which the reference number first appears.

FIG. 1 is a cross-sectional view of an exemplary multijunction VCSEL structure.

FIG. 2A schematically illustrates a cross-sectional view of a multijunction VCSEL array after a process of epitaxial growth, according to one embodiment of the present invention.

FIGS. 2B and 2C schematically illustrate a top view and a cross-sectional view of the VCSEL array shown in FIG. 2A after etching and oxidation processes are performed, according to one embodiment of the present invention.

FIGS. 2D and 2E schematically illustrate cross-sectional views of the VCSEL array shown in FIGS. 2B and 2C after deposition steps are performed, according to one embodiment of the present invention.

FIGS. 2F and 2G schematically illustrate cross-sectional views of the VCSEL array shown in FIG. 2E after assembly steps are performed, according to embodiments of the present invention.

FIG. 3A schematically illustrates a cross-sectional view of a multijunction VCSEL array after a process of epitaxial growth, according to one embodiment of the present invention.

FIGS. 3B and 3C schematically illustrate a top view and a cross-sectional view of the VCSEL array shown in FIG. 3A after etching and oxidation processes are performed, according to one embodiment of the present invention.

FIGS. 3D and 3E schematically illustrate cross-sectional views of the VCSEL array shown in FIGS. 3B and 3C after deposition steps are performed, according to one embodiment of the present invention.

FIGS. 3F and 3G schematically illustrate cross-sectional views of the VCSEL array shown in FIG. 3E after assembly steps are performed, according to embodiments of the present invention.

FIG. 4A schematically illustrates a cross-sectional view of a multijunction VCSEL array after a process of epitaxial growth, according to one embodiment of the present invention.

FIGS. 4B and 4C schematically illustrate a top view and a cross-sectional view of the VCSEL array shown in FIG. 4A after etching and oxidation processes are performed, according to one embodiment of the present invention.

FIGS. 4D, 4E, 4F, and 4G schematically illustrate cross-sectional views and a top view of the VCSEL array shown in FIGS. 4B and 4C after deposition steps are performed, according to one embodiment of the present invention.

FIG. 4H schematically illustrates a cross-sectional view of the VCSEL array shown in FIGS. 4F and 4G after assembly steps are performed, according to one embodiment of the present invention.

### DETAILED DESCRIPTION

Detailed description of the present invention is provided below along with figures and embodiments, which further clarifies the objectives, technical solutions, and advantages of the present invention. It is noted that schematic embodiments discussed herein are merely for illustrating the invention. The present invention is not limited to the embodiments disclosed.

FIG. 1 shows a multijunction VCSEL 100 in a cross-sectional view. VCSEL 100 may be one of the VCSEL emitters of a VCSEL array. The VCSEL emitters may be separated by isolation structures. The VCSEL array may include thousands or tens of thousands of VCSEL emitters or VCSELs. In other figures and descriptions below, only a few VCSELs are used for explaining principles and methods of a VCSEL array. VCSEL 100 represents a top-emitting VCSEL structure or a top-emitting VCSEL emitter which emits a laser beam through the top surface when charged with an electrical current. As used herein, a VCSEL, VCSEL structure, and VCSEL emitter have the same meaning and may be used interchangeably.

As shown in FIG. 1, VCSEL 100 exemplarily includes a multijunction active region 101, a top reflector region 102, and a bottom reflector region 103, each of which include layers grown epitaxially above a substrate 104. Multijunction active region 101 contains multi quantum well (MQW) active regions, oxide layers, and at least one tunnel junction structure. For example, multijunction active region 101 may include MQW active regions 105, 106, and 107, oxide layers 108, 109, and 110, and tunnel junction structures 111 and 112. Oxide layers 108, 109, and 110 are configured to form three oxide apertures, such as an oxide aperture 113 formed by oxide layer 108. In some embodiments, a multijunction VCSEL may have fewer MQW active regions, fewer oxide layers, and fewer tunnel junction structures. For example, a VCSEL may have a structure similar to that of VCSEL 100, e.g., having MQW active regions 105 and 106, oxide layers 108 and 109, and tunnel junction structure 111, but may not have tunnel layer 112, oxide layer 110, and MQW active region 107. That is, a multijunction VCSEL may have two MQW active regions, two oxide layers, and one tunnel junction structure. In some other embodiments, a multijunction VCSEL may have more MQW regions, more oxide layers, and more tunnel junction structures than VCSEL 100. For example, a multijunction VCSEL may have N MQW active regions, N oxide layers, and N-1 tunnel junction structures, where N is an integer larger than 3, e.g., N may be 4 or 5.

Top reflector region 102 may contain a p-type Distributed Bragg Reflector (DBR). Bottom reflector region 103 may contain an n-type DBR. Substrate 104 may include, for example, a conductive n-type gallium arsenide (GaAs) substrate. The quantum well layers, tunnel junction structures, and DBRs may be grown above substrate 104 in an epitaxial process. Reflector regions 102 and 103 are electrically conductive. A metal layer 114 may be deposited on the top surface of reflector region 102, followed by deposition of a dielectric layer (not shown). On the bottom surface of substrate 104, a metal layer 115 may be deposited. Metal layers 114 and 115 serve as the anode and cathode contacts, respectively. VCSEL 100 may be separated from other VCSELs (not shown) by isolation region 116. Isolation region 116 may be a trench filled with a dielectric material.

During VCSEL operation, the majority of heat comes from the active region. For a multijunction VCSEL with multiple active regions, the heat generated in the VCSEL may be approximately proportional to the number of active regions. That is, when the number of active regions is increased in a VCSEL structure for achieving higher output power, the heat generated is also increased and overheating issues may become worse. Hence, thermal management of multijunction VCSEL is an important factor for reliability, opto-electric performances, and intensity uniformity.

As shown in FIG. 1, multijunction active region 101 is closer to the top surface of reflector region 102 than the bottom surface of substrate 104 (or metal layer 115). As aforementioned, the substrate thickness is around 100-600 micrometers. Then, the distance between active region 101 and the bottom surface of substrate 104 may be ten times or more than ten times of that between active region 101 and the top surface of reflector region 102. For a top-emitting VCSEL, the substrate is bonded to a submount. For a bottom-emitting VCSEL, a pad metal layer on the top reflector region is bonded to a submount in a flip-chip process. Therefore, the active region of a bottom-emitting VCSEL is much closer to the submount than that of a top-emitting VCSEL. The closer the active region to a submount, i.e., the heat sink, the more efficient the heat dissipation becomes. Hence, heat dissipation of a bottom-emitting VCSEL is inherently better than that of a top-emitting VCSEL. Therefore, compared to a top-emitting VCSEL, a bottom-emitting VCSEL has improved heat dissipation. That is, a bottom-emitting multijunction VCSEL is advantageous over a top-emitting multijunction VCSEL in terms of heat management. In addition, a bottom-emitting VCSEL chip is often bonded to a submount without using bonding wires. Hence, it supports operations of short-pulse mode, e.g., nanosecond-pulse mode.

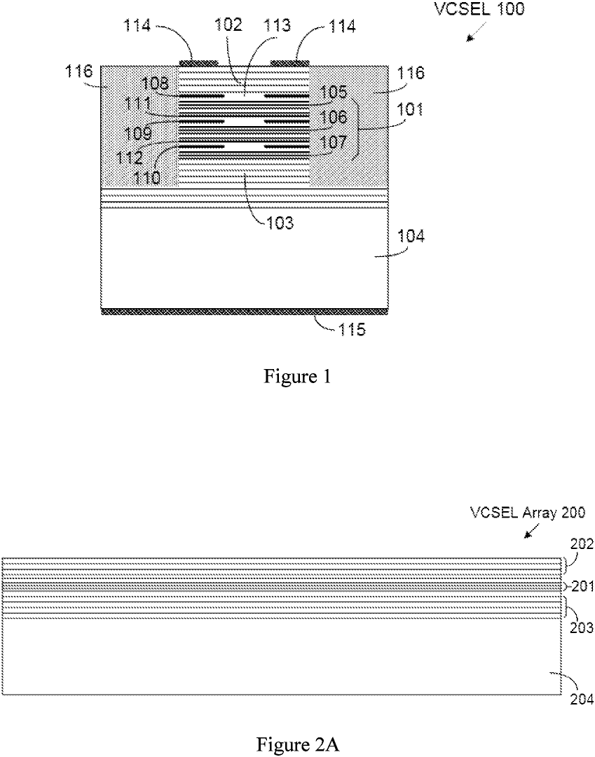

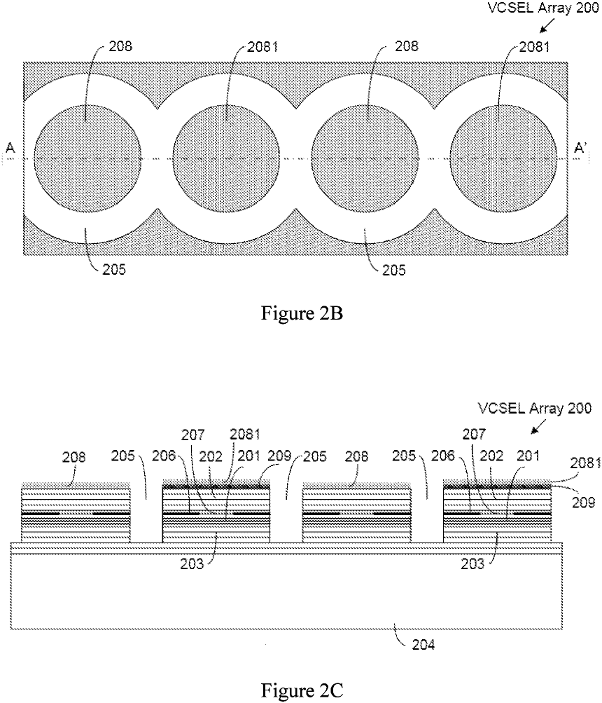

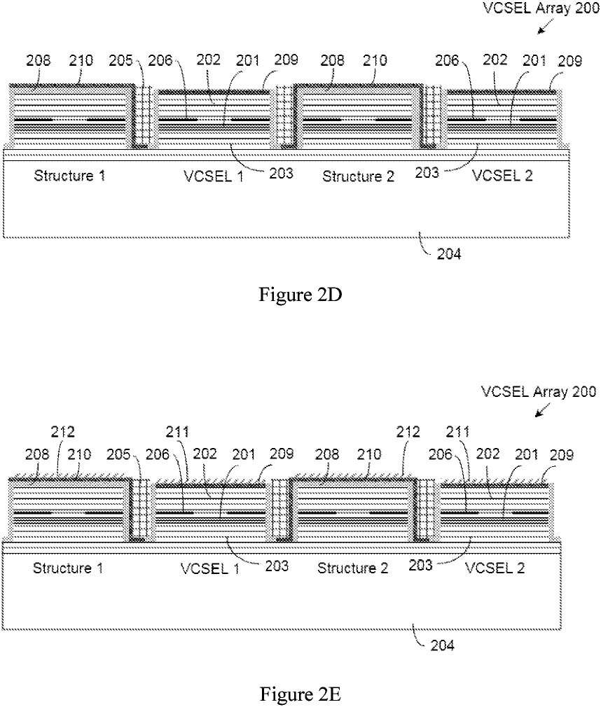

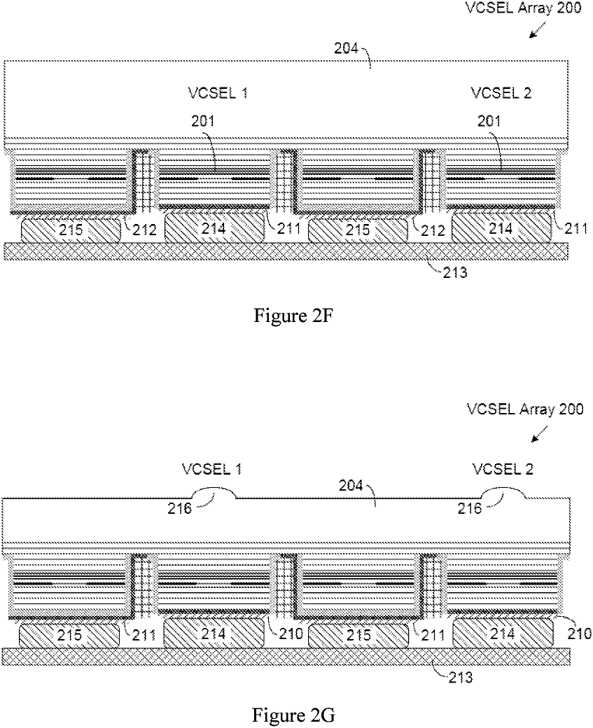

FIGS. 2A, 2B, and 2C each schematically illustrate a bottom-emitting multijunction VCSEL array 200 according to embodiments of the present invention. FIGS. 2A and 2C are cross-sectional views of array 200 or a chip containing array 200, while FIG. 2B is a top view. FIG. 2C shows a cross-sectional view along a line AA’ of FIG. 2B. As shown in FIG. 2A, array 200 may include a multijunction active region 201, a top reflector region 202, and a bottom reflector region 203. Regions 201, 202, and 203 each include multiple layers that are grown epitaxially above a substrate 204. Top and bottom reflector regions 202 and 203 may include a conductive p-type DBR and a conductive n-type DBR structure, respectively. In some embodiments, substrate 204 may include an n-type substrate, such as an n-type GaAs substrate or indium phosphide (InP) substrate. In some embodiments, substrate 204 may include an undoped substrate, such as an undoped GaAs substrate or InP substrate. Multijunction active region 201 may include MQW active regions (not shown), oxide layers (not shown), and at least one tunnel junction structure (not shown). For example, multijunction active region 201 may include N MQW active regions, N oxide layers, and N-1 tunnel junction structures, where N is an integer larger than 1, e.g., N may be 3, 4 or 5.

Because substrate 204 may have a thickness of 100-600 micrometers, the distance between active region 201, i.e., the main heat source, and the bottom surface of substrate 204 may be ten times or more of that between active region 201 and the top surface of region 202. Hence, the path of heat dissipation of a top-emitting VCSEL, where substrate 204 is attached to a submount, may be, e.g., ten times longer than that of a bottom-emitting VCSEL, where the top side of array 200 is attached to a submount. As such, a bottom-emitting VCSEL structure may dissipate heat more efficiently than a top-emitting VCSEL structure, and a bottom-emitting multijunction VCSEL array may overcome overheating issues more efficiently than a top-emitting multijunction VCSEL array.

Regions 203, 201, and 202 are formed sequentially in an epitaxial growth process. For example, region 203 may be grown epitaxially above substrate 204, region 201 may be grown epitaxially above region 203, and region 202 may be grown epitaxially above region 201. After regions 201-203 are formed in the epitaxial growth process, a metal deposition process may be performed to form a metal layer 209 on parts of region 202. Metal layer 209 electrically contacts the p+ layer of the DBR structure and thus is electrically connected to top reflector region 202. Then, a dielectric layer 208 (including 2081) with a material, such as silicon nitride or silicon oxide, may be deposited.

Thereafter, a selective etch process, such as a selective dry etch or dry and wet etch processes, may be performed to form an isolation trench 205 that separates the VCSELs of array 200. In some embodiments, trench 205 may form, for example, connected rings in a horizontal plane, such as that shown in FIG. 2B. Each ring may surround a VCSEL structure or a dummy VCSEL structure. “Dummy VCSEL structure”, as used herein, may indicate a structure that is similar to some parts of a VCSEL structure, but is not made to be a VCSEL structure and does not function as a VCSEL. In some embodiments, trench 205 may extend vertically through top reflector region 202, multijunction active region 201, and partially through bottom reflector region 203, as shown in FIG. 2C. Then, portions of the n-type DBR structure of bottom reflector region 203 are exposed. The selective etch process also exposes sides of aluminum (Al)-rich or relatively high Al-content layers that are arranged adjacent to each MQW active region of multijunction active region 201.

Then, a wet oxidation process may be performed to oxidize the Al-rich layers and form multiple oxide layers. One of the oxide layers, such as an oxide layer 206, is illustrated schematically in FIG. 2C. Oxide layer 206 is arranged to form an oxide aperture 207 for each VCSEL emitter. A laser output beam of each VCSEL emitter is aligned with oxide aperture 207. As shown in FIG. 2C, top reflector region 202, oxide aperture 207, multijunction active region 201, and bottom reflector 203 form an optical cavity or laser cavity. Oxide aperture 207 not only serves to form the laser cavity, but also to direct electrical currents through the central region of the cavity.

FIGS. 2D and 2E schematically illustrate VCSEL array 200 in cross-sectional views after certain fabrication processes according to embodiments of the present invention. After the oxidation process, a dielectric layer may be deposited on the sidewall and bottom surface of trench 205. The dielectric layer may include, for example, a silicon oxide layer or a silicon nitride layer. Then, a selective dry etch may be performed to etch out a portion of the dielectric layer at the bottom of trench 205, which exposes parts of region 203. Subsequently, a metal layer 210 may be deposited on the exposed parts of region 203 at the bottom of trench 205. Metal layer 210 electrically contacts bottom reflector region 203 and also extends to cover parts of layer 208 that are on top of dummy VCSEL structures 1 and 2, as shown in FIG. 2D. Next, trenches 205 may be filled with a dielectric material, such as polyimide, silicon oxide, or silicon nitride, and layer 2081 may be etched away to expose metal layers 209, as shown in FIG. 2D. As metal layers 209 and 210 are exposed on top of VCSELs 1 and 2 and dummy structures 1 and 2, a metal deposition process may be performed to form pad metal layers 211 and 212. Pad metal layer 211, as the anode contact of array 200, may be deposited on metal layer 209, and pad metal layer 212, as the cathode contact of array 200, may be deposited on metal layer 210, as shown in FIG. 2E.

FIGS. 2F and 2G schematically illustrate VCSEL array 200 in cross-sectional views after assembly processes according to embodiments of the present invention. As VCSEL array 200 is configured bottom emitting, the VCSEL chip is attached to a submount 213 by, e.g., a flip-chip bonding method, as shown in FIG. 2F. In the assembly, the bottom surface of substrate 204 faces upward and faces a direction away from submount 213. Pad metal layers 211 and 212 face submount 213 downwardly and are disposed between substrate 204 and submount 213. An electrically conductive adhesive material 214 is used to electrically contact pad metal layer 211, and an electrically conductive adhesive material 215 is used to electrically contact pad metal layer 212. Materials 214 and 215 bond VCSEL array 200 on submount 213, and electrically connect pad metal layer 211 (the anode) and pad metal layer 212 (the cathode) to plated metal layers (not shown) arranged on submount 213. As such, bonding wires are not needed for electrical connection between VCSEL array 200 and submount 213. Submount 213 may be configured as a heat sink made of materials with high thermal conductivity. Compared with a top-emitting VCSEL array where a substrate is between the active region and the submount, a bottom-emitting VCSEL is flip-chip bonded and thus the active region becomes much closer to the submount, i.e., the heat sink. Hence, heat generated by multijunction active region 201 may be dissipated more efficiently with a flip-chip assembly.

As shown in FIG. 2G, the bottom surface of substrate 204 is at the top of the assembly, and thus the bottom surface may be selectively etched to form an array of micro-lens 216 by a dry etch or dry and wet etch processes. Micro-lens 215 is configured to collimate an output laser beam coming out from VCSEL 1 or 2. Then, VCSEL array 200 may produce an array of collimated beams that are desirable in some 3D sensing applications.

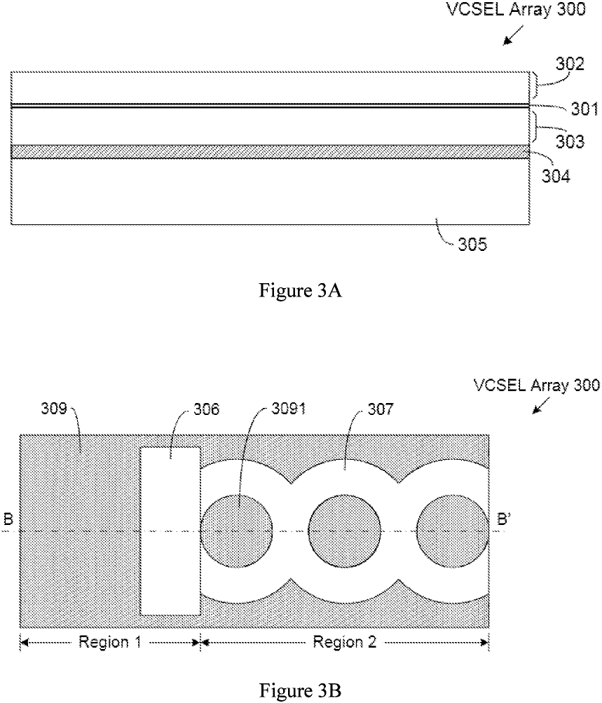

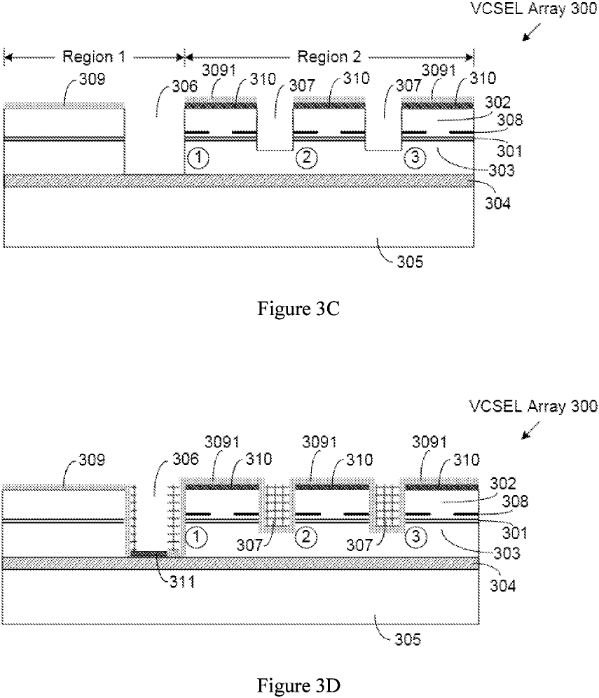

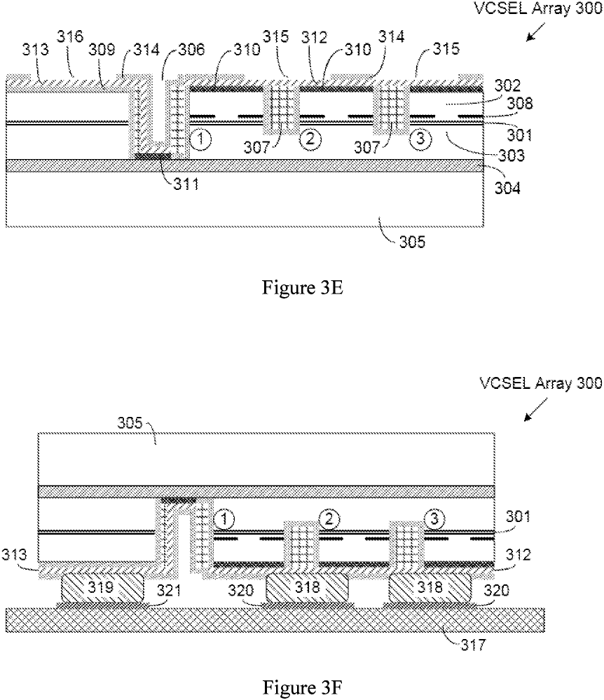

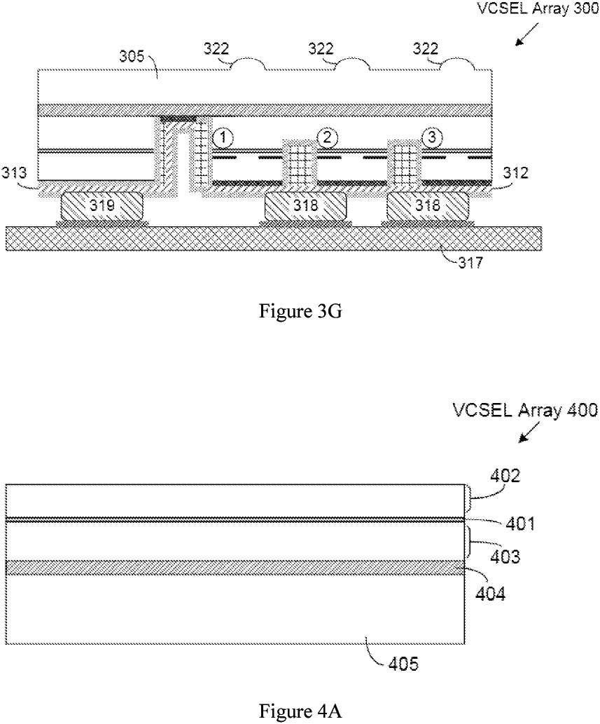

FIGS. 3A, 3B, and 3C each schematically illustrate a bottom-emitting multijunction VCSEL array 300 according to embodiments of the present invention. FIGS. 3A and 3C are cross-sectional views of array 300 or a chip containing array 300, while FIG. 3B is a top view. FIG. 3C shows a cross-sectional view along a line BB’ of FIG. 3B. As shown in FIG. 3A, array 300 may include a multijunction active region 301, a top reflector region 302, a bottom reflector region 303, and a conductive n+ contact layer 304. Lines representing epitaxial layers of regions 302 and 303 are not shown in FIGS. 3A, 3C, and following figures for simplicity. Regions 301-303 and layer 304 are grown above a substrate 305, such as a GaAs substrate or InP substrate that may be undoped or lightly doped with n-type dopants. Top and bottom reflector regions 302 and 303 may include a conductive p-type DBR and a conductive n-type DBR structure, respectively. Layer 304 is configured as a contact layer for the cathode electrode of a VCSEL emitter. Multijunction active region 301 may include MQW active regions (not shown), oxide layers (not shown), and at least one tunnel junction structure (not shown). For example, multijunction active region 301 may include N MQW active regions, N oxide layers, and N-1 tunnel junction structures, where N is an integer larger than 1, e.g., N may be 3, 4 or 5.

Layer 304 and regions 303, 301, and 302 are formed sequentially in an epitaxial process. For example, layer 304 may be grown epitaxially above substrate 305, region 303 may be grown epitaxially above layer 304, region 301 may be grown epitaxially above region 303, and region 302 may be grown epitaxially above region 301. After regions 301-303 are deposited in the epitaxial growth, a deposition process may be performed to deposit a metal layer 310 on a top surface of region 302. Metal layer 310 electrically contacts the p+ layer of the DBR structure and thus is electrically connected to top reflector region 302. Then, a dielectric layer 309 (including 3091) with material such as silicon nitride or silicon oxide may be deposited.

Thereafter, a first selective etch process, such as a selective dry etch or dry and wet etch processes, may be performed to form an isolation trench 307. The first selective etch process exposes sides of Al-rich or relatively high Al-content layers that are arranged adjacent to each MQW active region of multijunction active region 301. Then, a wet oxidation process may be performed to oxidize the Al-rich layers and form multiple oxide layers. One of the oxide layers, such as an oxide layer 308, is illustrated schematically in FIG. 3C. Oxide layer 308 is arranged to form an oxide aperture for each VCSEL emitter. A laser output beam of each VCSEL emitter is aligned with the oxide aperture. After the wet oxidation process, a second selective etch process, such as a selective dry etch or dry and wet etch processes, may be performed to form an isolation trench 306.

Trench 306 may be arranged in a region 1 above substrate 305 that is beside a region 2 where a group of VCSEL emitters, such as VCSEL emitters 1, 2, and 3, are configured. VCSELs emitters 1, 2, and 3 are illustrated with signs “1”, “2”, and “3” in FIG. 3C, respectively. As such, trench 306 is outside region 2, i.e., the region of the VCSELs, and not configured for the purpose of separating the VCSELs.

In some embodiments, trench 306 may have a rectangular shape in a horizontal plane, such as that shown in FIG. 3B. In some other embodiments, trench 306 may have another regular or an irregular shape in the horizontal plane. In some embodiments, trench 306 may adjoin trench 307 in a horizontal plane, such as that shown in FIG. 3B. In some other embodiments, trench 306 may be separated from trench 307 in the horizontal plane. Trench 306 may extend vertically through top reflector region 302, multijunction active region 301, and bottom reflector region 303, and reach and expose n+ contact layer 304.

Trench 307 is formed to separate VCSEL emitters 1, 2, and 3. For example, parts of trench 307 may be arranged between VCSEL emitters 1 and 2 and between emitters 2 and 3, respectively. Trench 307 may have a connected-ring shape and each ring surrounds a VCSEL emitter in the horizontal plane. Trench 307 may extend vertically through top reflector region 302, multijunction active region 301, and through or partially through bottom reflector region 303.

In some other embodiments, trenches 306 and 307 may be formed simultaneously in one selective etch process, e.g., the first selective etch process. Hence, the process to form the trenches may be simplified. In such a scenario, both trenches 306 and 307 may extend vertically through top reflector region 302, multijunction active region 301, and bottom reflector region 303, and reach and expose n+ contact layer 304.

FIGS. 3D and 3E schematically illustrate VCSEL array 300 in cross-sectional views after some fabrication processes according to embodiments of the present invention. After the wet oxidation process, a dielectric layer may be deposited on the sidewalls and bottom surfaces of trenches 306 and 307. The dielectric layer may include, for example, a silicon oxide layer or a silicon nitride layer. Then, a selective dry etch may be performed to etch out a portion of the dielectric layer at the bottom of trench 306, which exposes a part of layer 304. Subsequently, a metal layer 311 may be deposited on the exposed part of layer 304 at the bottom of trench 306. Metal layer 311 electrically contacts n+ contact layer 304 and is made as the contact metal for the cathode.

Next, a dielectric material may be deposited and trench 307 may be filled with the dielectric material, such as polyimide, silicon oxide, or silicon nitride. The dielectric material may be used to make the sidewall of trench 306 thicker. In some other embodiments, trench 307 may be filled with a conductive material, e.g., a metal. After trench 307 is filled, layer 3091 may be etched out to expose metal layer 310. As metal layers 310 and 311 are exposed on top of VCSELs 1-3 and at the bottom of trench 306, a metal deposition process may be performed to form pad metal layers 312 and 313. Pad metal layer 312, as the anode contact of array 300, covers metal layer 310, and pad metal layer 313, as the cathode contact of array 300, covers metal layer 311. Pad metal layer 313 also extends to cover a part of isolation layer 309 that is adjacent to trench 306 in region 1, as shown in FIG. 3E. In some embodiments, pad metal layers 312 and 313 may include a thin layer of gold with a thickness between two to five micrometers.

After pad metal layers 312 and 313 are formed, another dielectric layer 314, such as a silicon oxide layer, aluminum oxide layer, or silicon nitride layer, may be deposited to cover the pad metal layers and other areas that are exposed. Then, a selective etch, such as a selective dry etch, may be performed to etch away some portions of layer 314 to expose parts of pad metal layers 312 and 313. For example, two portions of layer 314 may be removed to form openings 315 and one portion of layer 314 may be removed to form an opening 316, as shown in FIG. 3E.

FIGS. 3F and 3G schematically illustrate VCSEL array 300 in cross-sectional views after some assembly processes according to embodiments of the present invention. FIG. 3F schematically shows that the bottom-emitting VCSEL array chip is attached to a submount 317 by, for example, flip-chip bonding. In the assembly, the bottom surface of substrate 305 faces upward and faces a direction away from submount 317. Pad metal layers 312 and 313 face submount 317 downwardly and are arranged between substrate 305 and submount 317. An electrically conductive adhesive material 318 is used to electrically contact pad metal layer 312 (the anode), and an electrically conductive adhesive material 319 is used to electrically contact pad metal layer 313 (the cathode). Materials 318 and 319 bond VCSEL array 300 on metal layers 320 and 321, respectively. Metal layers 320 and 321, deposited on submount 317, may be electrically connected to the p-bus line and n-bus line, respectively. As such, bonding wires are not needed for electrical connection between VCSEL array 300 and submount 317. Similar to submount 213 used to mount VCSEL array 200, submount 317 may be configured as a heat sink and may be made of materials with high thermal conductivity. Hence similarly, heat dissipation of bottom-emitting multijunction VCSEL array 300 may be improved with the flip-chip assembly.

As shown in FIG. 3G, the bottom surface of substrate 305 may be selectively etched to form an array of micro-lens 322 by a dry etch or dry and wet etch processes. Micro-lens 320 is configured to collimate an output laser beam coming out from the laser cavity of a VCSEL emitter. As such, VCSEL array 300 may generate an array collimated beams that are desirable in some 3D sensing applications.

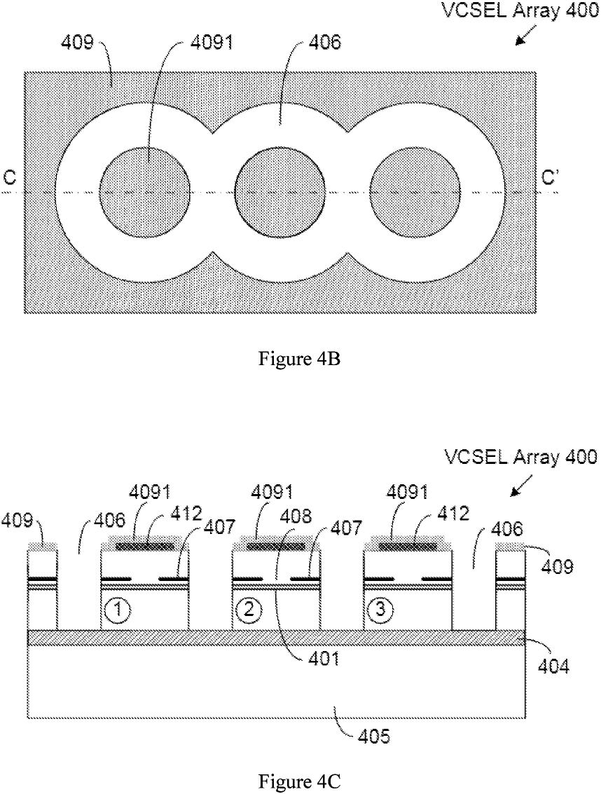

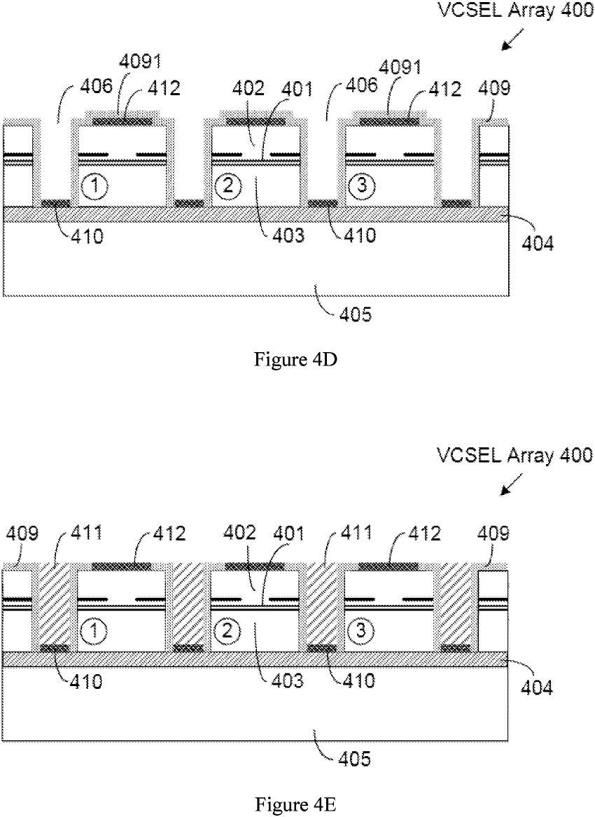

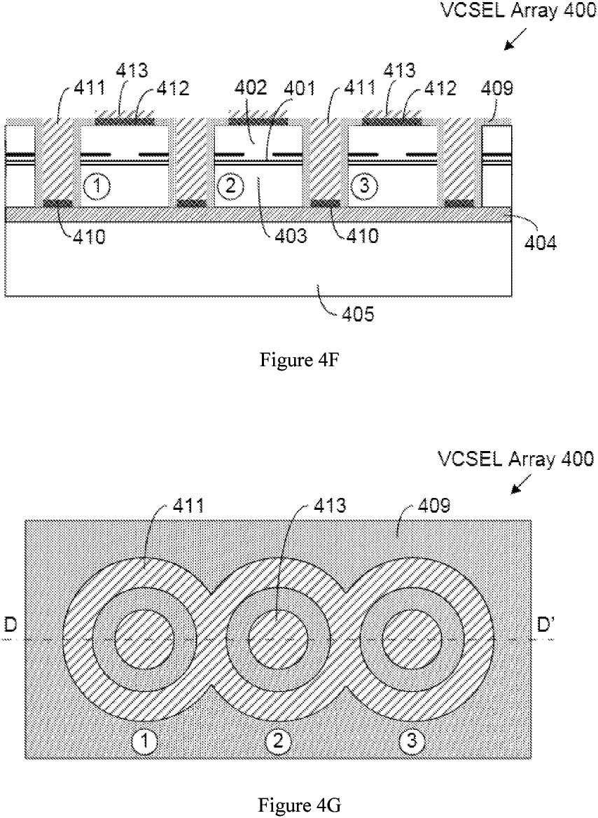

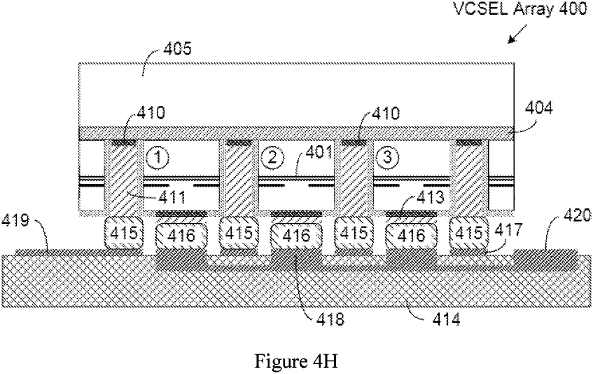

FIGS. 4A, 4B, and 4C each schematically illustrate a bottom-emitting multijunction VCSEL array 400 according to embodiments of the present invention. FIGS. 4A and 4C are cross-sectional views of array 400 or a chip containing array 400, while FIG. 4B is a top view. FIG. 4C shows a cross-sectional view along a line CC’ of FIG. 4B. As shown in FIG. 4A, array 400 may include a multijunction active region 401, a top reflector region 402, a bottom reflector region 403, and a conductive n+ contact layer 404. Lines representing epitaxial layers of regions 402 and 403 are not shown in FIGS. 4A, 4C, and following figures for simplicity. Similar to regions 301-303 and layer 304 of array 300, regions 401-403 and layer 404 are grown epitaxially above a substrate 405, such as a GaAs substrate or InP substrate. The substrate may be undoped or doped with n-type dopants. Top and bottom reflector regions 402 and 403 may include a conductive p-type DBR and a conductive n-type DBR structure, respectively. Layer 404 is configured as a contact layer for the cathode electrode of a VCSEL emitter. Multijunction active region 401 may include MQW active regions (not shown), oxide layers (not shown), and at least one tunnel junction structure (not shown). For example, multijunction active region 401 may include N MQW active regions, N oxide layers, and N-1 tunnel junction structures, where N is an integer larger than 1, e.g., N may be 3, 4 or 5.

After regions 401-403 are deposited epitaxially, a deposition process may be performed to deposit a metal layer 412 on a top surface of region 402. Metal layer 412 electrically contacts the p+ layer of the p-type DBR structure and is electrically connected to top reflector region 402. Next, a dielectric layer 409 (including 4091) with material, such as silicon nitride or silicon oxide, may be deposited.

Thereafter, a selective etch process, such as a selective dry etch or dry and wet etch processes, may be performed to form a trench 406. Trench 406 may be used to separate VCSEL emitters, such as VCSEL emitters 1, 2, and 3. VCSELs emitters 1, 2, and 3 are illustrated with signs “1”, “2”, and “3” in FIG. 4C, respectively. In some embodiments, the cross-section of trenches 406 may include, for example, a connected ring shape in a horizontal plane, as shown in FIG. 4B. Each ring may surround a VCSEL emitter. In some other embodiments, trench 406 may include individual rings that are separated from each other and each surround a VCSEL structure. In some other embodiments, trench 406 may include one or more shapes other than a ring shape that are separated from each other and surround VCSELs 1-3 respectively. Trench 406 may extend vertically through top reflector region 402, multijunction active region 401, and bottom reflector region 403, and reach and expose n+ contact layer 404.

Trench 406 exposes sides of Al-rich or relatively high Al-content layers that are arranged adjacent to each MQW active region of multijunction active region 401. Then, a wet oxidation process may be performed to oxidize the Al-rich layers and form multiple oxide layers. One of the oxide layers, such as an oxide layer 407, is illustrated schematically in FIG. 4C. Oxide layer 407 is arranged to form an oxide aperture 408 for each VCSEL emitter. A laser output beam of each VCSEL emitter is aligned with oxide aperture 408.

FIGS. 4D, 4E, and 4F schematically illustrate VCSEL array 400 in cross-sectional views after some fabrication processes according to embodiments of the present invention. After the wet oxidation process, a process is performed to deposit a dielectric layer on the sidewall and bottom surface of trench 406. Then, a portion of the dielectric layer on the bottom surface of trench 406 may be etched out to expose conductive layer 404. After layer 404 is exposed at the bottom of trench 406, a contact metal layer 410 may be deposited on the exposed part of layer 404, as shown in FIG. 4E. Then, a pad metal layer 411 may be deposited on metal layer 410. Pad metal layer 411 also may fill trench 406 and is used as the anode contact of array 400, as shown in FIG. 4E.

Thereafter, a selective etch, such as a selective dry etch, may be performed to etch out layer 4091 that covers metal layers 412 of VCSELs 1, 2, and 3. Then, layers 412 are exposed, as shown in FIG. 4E. Next, pad metal layers 413 may be deposited on metal layers 412 as the anode contact of array 400, as shown in FIG. 4F.

FIG. 4G schematically illustrates VCSEL array 400 in a top view after pad metal layers 411 and 413 are deposited according to embodiments of the present invention. The cross-sectional view of FIG. 4F is along a line DD’ of FIG. 4G. As shown in FIGS. 4F and 4G, pad metal layer 411 surrounds VCSELs 1, 2, and 3 horizontally and extends vertically through top reflector region 402, multijunction active region 401, and bottom reflector region 403, adjoins contact metal layers 410, and electrically connects with n+ contact layer 404. As described above, in some embodiments, pad metal layer 411 may have another shape or separate trench portions surrounding VCSELs 1, 2, and 3 in a horizontal plane.

FIG. 4H schematically illustrates a VCSEL array 400 in a cross-sectional view after some assembly processes according to embodiments of the present invention. As shown in FIG. 4H, the chip of bottom-emitting VCSEL array 400 is bonded on a submount 414 by flip-chip bonding. As such, the bottom surface of substrate 405 faces upward and faces a direction away from submount 414. Pad metal layers 411 and 413 face submount 414 downwardly and are configured between substrate 405 and submount 414. An electrically conductive adhesive material 415 is used to electrically contact pad metal layer 411 (the cathode), and an electrically conductive adhesive material 416 is used to electrically contact pad metal layer 413 (the anode). Materials 415 and 416 bond VCSEL array 400 on metal layers 417 and 418 on submount 414, respectively. Then, pad metal layers 411 and 413 are electrically connected with metal layers 417 and 418, respectively. Metal layers 417 and 418, formed on submount 414, may be electrically connected to contact pads 419 and 420, respectively. In some embodiments, metal layers 417 and 418 may have multiple layers for electrical connection as shown in FIG. 4H. Thus, bonding wires are not needed for electrical connection between VCSEL array 400 and submount 414. Similar to submount 213 used to mount VCSEL array 200 and submount 317 used to mount VCSEL array 300, submount 414 may be configured as a heat sink and may be made of materials with high thermal conductivity. Hence similarly, heat dissipation of bottom-emitting multijunction VCSEL array 400 may be improved with the flip-chip assembly.

In some embodiments, for the above-described examples, an epitaxial growth, such as the epitaxial growth of multijunction active region 201 or 301, top reflector region 202 or 302, bottom reflector region 203 or 303, or n+ contact layer 304, may be performed by metalorganic chemical vapor deposition (MOCVD). In some embodiments, an isolation layer, e.g., silicon oxide layer or silicon nitride layer, and/or a metal layer may be deposited by chemical vapor deposition (CVD), physical vapor deposition (PVD), or atomic layer deposition (ALD). In some embodiments, an isolation layer, e.g., silicon oxide layer or silicon nitride layer, and/or a metal layer may be deposited by a combination of at least two of CVD, PVD, and ALD.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments. Furthermore, it is intended that the appended claims cover any and all such applications, modifications, and embodiments within the scope of the present invention.

1. A Vertical Cavity Surface Emitting Laser (VCSEL) array device, comprising:
a submount; and
a VCSEL array chip attached to the submount, the VCSEL array chip comprising:
a substrate; and
a plurality of VCSEL structures formed in a first chip region above the substrate, each VCSEL structure comprising:
a first reflector region formed above the substrate;
a multijunction active region including a plurality of multiple-quantum-well (MQW) active regions formed above the first reflector region;
a second reflector region formed above the multijunction active region; and
a pad metal layer formed above the second reflector region,
wherein the pad metal layer faces the submount and is between the substrate and the submount after the VCSEL array chip is attached to the submount.

2. The VCSEL array device of claim 1, wherein the first reflector region and the second reflector region each comprise a Distributed Bragg Reflector (DBR) structure.

3. The VCSEL array device of claim 1 further comprises a first metal layer electrically connected to the first reflector region and a second metal layer electrically connected to the second reflector region.

4. The VCSEL array device of claim 1 further comprises a plurality of lenses formed on a surface of the substrate.

5. The VCSEL array device of claim 1 further comprises a contact layer formed between the first reflector region and the substrate.

6. The VCSEL array device of claim 5 further comprises a third metal layer electrically connected to the contact layer and a fourth metal layer electrically connected to the second reflector region.

7. The VCSEL array device of claim 6, wherein the third metal layer is outside the first chip region and the fourth metal layer is inside the first chip region.

8. A method for fabricating a Vertical Cavity Surface Emitting Laser (VCSEL) array device, comprising:
forming a plurality of VCSEL structures in a first chip region above a substrate of a VCSEL array chip; and
attaching the VCSEL array chip on a submount,
wherein forming the plurality of VCSEL structures comprises:
growing a first reflector region above the substrate;
growing a multijunction active region above the first reflector region;
growing a second reflector region above the multijunction active region; and
forming a pad metal layer above the second reflector region,
wherein the pad metal layer faces the submount and is between the substrate and the submount after the VCSEL array chip is attached on the submount.

9. The method of claim 8, wherein the first reflector region and the second reflector region each comprise a Distributed Bragg Reflector (DBR) structure.

10. The method of claim 8 further comprises depositing a first metal layer electrically connected to the first reflector region and a second metal layer electrically connected to the second reflector region.

11. The method of claim 8 further comprises forming a plurality of lenses on a surface of the substrate.

12. The method of claim 8 further comprises forming a contact layer between the first reflector region and the substrate.

13. The method of claim 12 further comprises depositing a third metal layer electrically connected to the contact layer and a fourth metal layer electrically connected to the second reflector region.

14. The method of claim 13, wherein the third metal layer is outside the first chip region and the fourth metal layer is inside the first chip region.

15. A Vertical Cavity Surface Emitting Laser (VCSEL) array device, comprising:
a submount; and
a VCSEL array chip attached to the submount, the VCSEL array chip comprising:
a substrate; and
a plurality of VCSEL structures formed in a first chip region above the substrate, each VCSEL structure comprising:
a contact layer formed above the substrate;
a first reflector region formed above the contact layer;
a multijunction active region formed above the first reflector region;
a second reflector region formed above the multijunction active region; and
a pad metal layer formed above the second reflector layer and electrically connected to the contact layer,
wherein the pad metal layer faces the submount and is between the substrate and the submount after the VCSEL array chip is attached to the submount.

16. The VCSEL array device of claim 15, wherein the first reflector region and the second reflector region each comprise a Distributed Bragg Reflector (DBR) structure.

17. The VCSEL array device of claim 15 further comprises a plurality of lenses formed on a surface of the substrate.

18. The VCSEL array device of claim 15, wherein the pad metal layer is outside the first chip region.

19. The VCSEL array device of claim 15, wherein the pad metal layer is inside the first chip region and extends through the second reflector region, the multijunction active region, and the first reflector region.

20. The VCSEL array device of claim 19, wherein the pad metal layer at least partially surrounds each VCSEL structure respectively.
